(19) United States
(12) Patent Application Publication
(10) Pub. No.: US 2022/0403851 A1
(43) Pub. Date: Dec. 22, 2022

(54) SPEED CONTROL METHOD OF DC MOTOR FAN

(71) Applicant: SUPER FLOWER COMPUTER INC., New Taipei City (TW)

(72) Inventors: Guo-Chuan Liu, NEW TAIPEI CITY (TW); Yong-hai Wang, Cao County (CN); Jin-zhong Luo, Nanchang City (CN); Tsung-Yen Tsa, NEW TAIPEI CITY (TW)

(21) Appl. No.: 17/749,673

(22) Filed: May 20, 2022

(30) Foreign Application Priority Data
Jun. 17, 2021 (TW) 110122189

(51) Int. Cl. F04D 27/00; F04D 25/06

(52) U.S. Cl. CPC F04D 27/004; F04D 25/06; H05K 7/20209

(57) ABSTRACT

A speed control method of direct current motor fans is revealed. The method used for starting and speed adjustment of the DC motor fan according to a temperature signal includes the following steps. First using a first voltage to start a DC motor fan during a start period and the first voltage is larger than the lowest voltage required for keeping the DC motor fan rotating. Then provide the DC motor fan with the lowest voltage which keeps the DC motor fan rotating during a low-load period after the start period. When a temperature represented by the temperature signal reaches a preset heat dissipation temperature range, a working voltage is adjusted proportionally and linearly according to the temperature signal for speed adjustment of the DC motor fan. The present method has advantages of high starting torque, noise cancellation, energy-saving, and low cost.

### BACKGROUND OF THE INVENTION

### Field of the Invention

The present invention relates to a control method of direct current (DC) motor fans, especially to a speed control method of DC motor fans.

### Description of Related Art

In order to prevent lower efficiency or failure of electronics caused by heat, most of electronics is equipped with cooling fans. At early stage, personal computers include no cooling fans and an old-type central processing unit (CPU) is provided with heat sinks for control of temperature within the acceptable range. Along with increasing speed and performance of the CPU, cooling fans now are essential for normal operation of the CPU. An old-type cooling fan is run at fixed speed once started, without providing the speed-control function. The fix-speed cooling fan has a shortcoming of fixed heat dissipation ability. The rotation speed needs to increase in order to improve heat dissipation ability while the higher the speed, the greater the noise. In order to overcome the above shortcoming and save power, the speed adjustment techniques of the cooling fan have been developed. Another reason we need to reduce the speed of the cooling fan is that the low-speed (or low-voltage) cooling fan is more expensive than others. A general cheap cooling fan has a higher rotating speed so that the noise generated is greater.

There are two common ways to control or regulate the speed of cooling fans. One is Voltage Control (VC) and Pulse Width Modulation (PWM). The proper speed control method is selected according to types and specifications of the cooling fan. A basic cooling fan has two wires while a direct current cooling fan includes a red wire for the positive current and a black wire for the negative current. In order to support more functions, 3-wire or 4-wire cooling fans have been developed and marketed. Besides the two basic wires, other wires are used as signal wires for providing different functions. The most common functions include (1) FG (frequency generation): the third wire which outputs a tachometer signal showing the speed at which the fan is running is a yellow wire (2) RD (rotation detection): for providing a rotation detection signal that indicates whether or not the fan is running normally and giving an alarm when the fan stops running (3) PWM (speed regulation): for control of the speed by modulation with the width of an impulse.

As to voltage control, the voltage supplied by the power wire is varied for control of the speed of the cooling fan. For example, the personal computer can be directly switched between 6.0 V-DC and 12.0 V-DC provided by the power supply for control of the speed of the cooling fan. The advantage of the voltage control is in that only a simple circuit is required. Even a cooling fan with two wires can be used to achieve the voltage control function. The cost of the cooling fan is low while the shortcoming of the cooling fan is in that the higher the speed of the cooling fan, the greater the power consumed and the noise generated. For example, the cooling fan is driven by the voltage 6.0 V-DC and at the lowest speed (such as 600 rpm). When the temperature is increased, the speed of the cooling fan is linearly increased to the maximum speed (such as 1200 rpm). Thus the cooling fan operates between 600 rpm and 1200 rpm. The power consumed and the noise generated are proportionally to the speed of the fan. Once a cheap cooling fan or a cooling fan with poor quality is used, noise generated at low-voltage speed is quite annoying. When the speed of the cooling fan is going up along with the increasing temperature, more noise is created in the working environment.

Refer to Taiwanese Pat. Pub. No. TW I451673B already granted, a fan speed control method and an apparatus for performing the method are revealed. The method comprises the following steps: generating a starting PWM signal by a fan driving unit and sending the starting PWM signal to a fan motor coil in a starting time period, and generating a steady PWM signal by the fan driving unit and sending the steady PWM signal to the fan motor coil when the starting time period is over. A duty ratio of the starting PWM signal is larger than that of the steady PWM signal. The fan speed control apparatus includes a control unit and the fan driving unit while the control unit has a voltage dividing circuit and a capacitor. Tow ends of the capacitor are connected with a high level terminal and a series connecting terminal of the voltage dividing circuit correspondingly and the fan driving unit connects with series connecting terminal to transfer an output voltage of the series connecting terminal into one of the starting or steady PWM signals.

The cooling fan which supports PWM has the advantages of effective temperature control or speed modulation of the cooling fan and significant reduction of noise. Yet the shortcoming is in that the cooling fan needs to have a built-in PWM Signal Control integrated circuit (IC). Thus the production cost is higher and PWM cooling fans are more expensive than others. If the PWM cooling fan is mounted to personal computers, the motherboard of the personal computer needs to support the PWM function.

### SUMMARY OF THE INVENTION

Therefore, it is a primary object of the present invention to provide a speed control method of direct current motor fans used for starting and speed adjustment of the DC motor fan according to a temperature signal and having advantages of high starting torque, noise cancellation, energy-saving and low cost. Thereby a general fan with low cost can achieve more efficient power output and provide more quiet and energy-saving operation during low load by using the present method.

In order to achieve the above object, a speed control method of direct current motor fans according to the present invention includes the following steps.

Using a first voltage to start the DC motor fan during a start period and providing the first voltage to the DC motor fan during the start period;

providing a second voltage to the DC motor fan during a low-load period which is just after the end of the start period while the second voltage is the lowest voltage required for keeping the DC motor fan rotating;

providing a working voltage to the DC motor fan when a temperature represented by a temperature signal reaches a preset temperature threshold or a heat dissipation temperature range above the preset temperature threshold, and then adjusting the working voltage proportionally and linearly according to the temperature signal within the heat dissipation temperature range; an upper limit of the working voltage is a rated voltage of the DC motor fan; and

turning back to the low-load period and providing the second voltage to the DC motor fan when the temperature represented by the temperature signal is dropped from the heat dissipation temperature range to be lower than the temperature threshold.

Preferably, the start period ranges from 3 to 10 seconds.

A speed control method of direct current motor fans according to the present invention includes the following steps.

Using a first voltage to start a DC motor fan during a start period and providing the first voltage to the DC motor fan during the start period;

providing a working voltage to the DC motor fan during a working period which is just after the end of the start period while an initial voltage of the working voltage is a second voltage which is the lowest voltage required for keeping the DC motor fan rotating; and

adjusting the working voltage proportionally and linearly according to the temperature signal during the working period and an upper limit of the working voltage is a rate voltage of the DC motor fan.

Preferably, the rated voltage of the DC motor fan is DC 12.0V while the first voltage is DC 5.0V and the second voltage is DC 3.0V.

The advantage of the present method is in that higher starting torque and starting efficiency are obtained by using the first voltage V1 which is higher than the second voltage to start the DC motor fan during the start period. Moreover, the second voltage is provided to the DC motor fan during a low-load period which is just after the end of the start period while the second voltage is the lowest voltage required for keeping the DC motor fan rotating. The DC motor fan keeps rotation due to rotation inertia when the voltage is dropped from the first voltage to the second voltage and the DC motor fan is having noise cancellation during the low-load period. A general DC motor fan with two wires can be used by the present method. Compared with the DC motor fan with three wires, four wires, or PWM function, the DC motor fan with two wires is more cost-effective.

### BRIEF DESCRIPTION OF THE DRAWINGS

The structure and the technical means adopted by the present invention to achieve the above and other objects can be best understood by referring to the following detailed description of the preferred embodiments and the accompanying drawings, wherein:

FIG. 1 is a schematic drawing showing a voltage control curve of an embodiment of a speed control method of direct current motor fan according to the present invention;

FIG. 2 is a schematic drawing showing a voltage control curve of another embodiment of a speed control method of direct current motor fan according to the present invention.

### DETAILED DESCRIPTION OF THE PREFERRED EMBODIMENT

The words including upper, lower, left and right used to describe positions in the following embodiments represent directions of embodiments shown in the figures unless otherwise defined. The direction-related words (such as upper, lower, left, right, front, and rear) mentioned are used to explain relative relationship between the respective components or structure of the embodiments such as positional relationship, connection relationship, and action relationship.

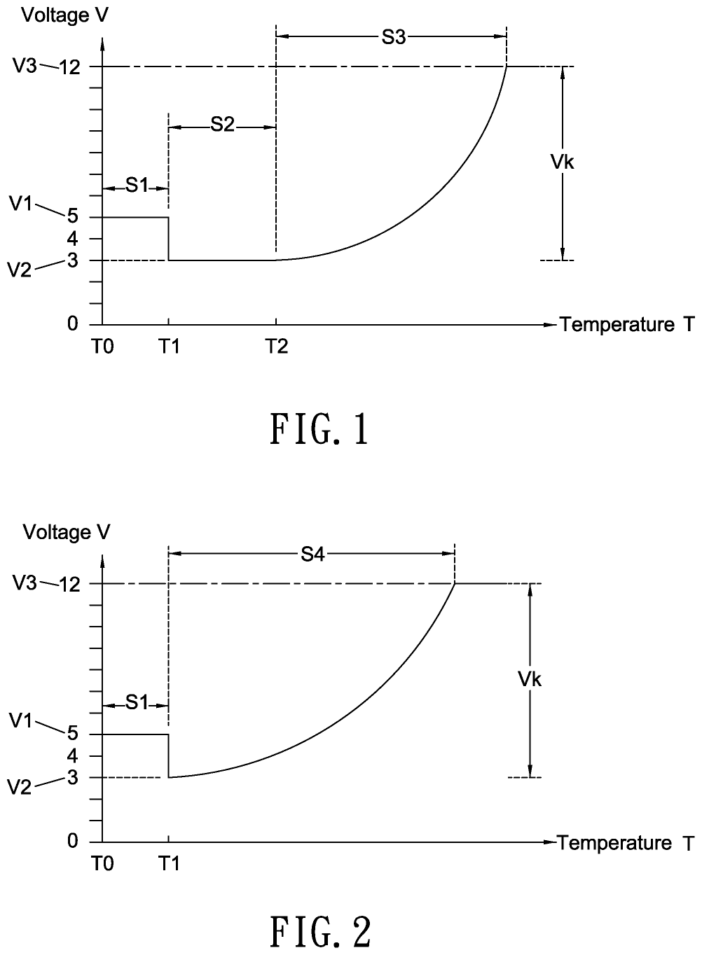

Refer to FIG. 1, a schematic drawing showing a voltage control curve of an embodiment of a speed control method of direct current (DC) motor fans according to the present invention is revealed. The present method used for starting and speed adjustment of the DC motor fan according to a temperature signal includes the following steps.

Using a first voltage V1 to start the DC motor fan during a start period S1 and providing the first voltage V1 to the DC motor fan during the start period S1;

providing a second voltage V2 to the DC motor fan during a low-load period S2 which is just after the end of the start period S1 while the second voltage V2 is the lowest voltage required for keeping the DC motor fan rotating;

providing a working voltage Vk to the DC motor fan when a temperature represented by a temperature signal reaches a preset temperature threshold T2 or a heat dissipation temperature range S3 above the temperature threshold T2 (that means the temperature represented by the temperature signal is equal to or larger than the preset temperature threshold T2). Then adjusting the working voltage Vk proportionally and linearly according to the temperature signal within the heat dissipation temperature range S3. That means the working voltage Vk is increased when the temperature is going up while the working voltage Vk is decreased when the temperature is going down. An upper limit of the working voltage Vk is the maximum voltage applied at which the DC motor fan can be operated safely and reliably (that's rated voltage V3); and

turning back to the low-load period S2 and providing the second voltage V2 to the DC motor fan when the temperature represented by the temperature signal is dropped from the heat dissipation temperature range S3 to be lower than the temperature threshold T2 (that means the temperature represented by the temperature signal is lower than the preset temperature threshold T2).

In a preferred embodiment, a general DC motor fan with two wires is used. Compared with the DC motor fan with three wires, four wires, or PWM function, the DC motor fan with two wires is more cost-effective. The present method can be applied to DC motor fans which are disposed on personal computers or power supplies for heat dissipation. A motherboard of the personal computer or a power supply is equipped with a temperature sensor for detecting temperature and obtaining a corresponding temperature signal. Then the DC motor fan is started and the speed is adjusted according to the temperature signal by using the present method.

In a preferred embodiment, the rated voltage V3 of the DC motor fan is DC 12.0V while the first voltage V1 is DC 5.0V and the second voltage V2 is DC 3.0V. The first voltage V1 is higher than the second voltage V2. Thus a larger starting torque is used to start the DC motor fan during starting and the starting efficiency is improved. Moreover, temperature equalization of the respective electronic components can be achieved within the start period S1 for heat dissipation in advance or pre-cooling. The temperature signal obtained by detection of the temperature sensor can be used to check whether the DC motor fan operates normally or not. For example, the start-up of the DC motor fan is abnormal when the temperature indicated by the temperature signal is abnormally raised during the start period S1. Although the motherboards or power supplies designed and produced by various companies have different specifications and performance, the temperature of the electronics will not be increased quickly during the short star-up period due to progress on manufacturing technology. Whether the DC motor fan is working normally or not can be determined by the above method that detects the temperature during the start period S1. In a preferred embodiment, the start period S1 is ranging from 3 to 10 seconds. Another advantage of the present method is in that the DC motor fan keeps rotation due to rotation inertia when the voltage is dropped from the first voltage V1 to the second voltage V2 and the DC motor fan is provided with noise cancellation during the low-load period S2.

As to the embodiment shown in FIG. 1, the initial temperature

TO before starting of the personal computer or the power supply should be room temperature under normal conditions. At the end of the start period S1, the temperature is increased a bit to a first temperature T1. The preset temperature threshold T2 of the present method which is larger than the first temperature T1 is not a fixed value, which varies with specifications and performance of motherboards or power suppliers designed and manufactured by different suppliers. Basically the temperature threshold T2 can be considered as the lowest temperature at which the heat dissipation mechanism should be activated. That means the speed of the DC motor fan should be adjusted to enhance heat dissipation effect during the low-load period when the temperature of the motherboard or the power supply is not less than the temperature threshold T2. Thereby the present method provides the DC motor fan with the lowest voltage (the second voltage V2) required for maintaining rotation when the temperature of the motherboard or the power supply is larger than the first temperature T1 while smaller than the temperature threshold T2. Noise generated by the rotating fan is reduced to achieve the noise cancellation. The method satisfies requirements for both heat dissipation and power saving while the system is during the low load. During the heat dissipation temperature range S3, the working voltage Vk is adjusted proportionally and linearly according to the temperature signal. Thereby the speed of the DC motor fan can be adjusted timely and appropriately for providing adequate heat dissipation.

Refer to FIG. 2, a schematic drawing showing a voltage control curve of another embodiment of a speed control method of DC motor fans according to the present invention is revealed. The method used for starting and speed adjustment of the DC motor fan according to a temperature signal shown in FIG. 2 includes the following steps.

Using a first voltage V1 to start the DC motor fan during a start period S1 and supplying the first voltage V1 to the DC motor fan during the start period S1;

providing a working voltage Vk to the DC motor fan during a working period S4 which is just after the end of the start period S1 while an initial voltage of the working voltage Vk is a second voltage V2 which is the lowest voltage required for keeping the DC motor fan rotating; and

adjusting the working voltage Vk proportionally and linearly according to the temperature signal during the working period S4. That means the working voltage Vk is increased when the temperature is going up and the working voltage Vk is lowered when the temperature is going down. An upper limit of the working voltage Vk is the maximum voltage applied at which the DC motor fan can be operated safely and reliably (that's rated voltage V3).

Additional advantages and modifications will readily occur to those skilled in the art. Therefore, the invention in its broader aspects is not limited to the specific details, and representative devices shown and described herein. Accordingly, various modifications may be made without departing from the spirit or scope of the general inventive concept as defined by the appended claims and their equivalent.

What is claimed is:

1. A speed control method of direct current (DC) motor fans for starting and speed adjustment of the DC motor fan according to a temperature signal comprising the steps of:
using a first voltage to start the DC motor fan during a start period and providing the first voltage to the DC motor fan during the start period;
providing a second voltage to the DC motor fan during a low-load period which is after the end of the start period while the second voltage is the lowest voltage required for keeping the DC motor fan rotating;
providing a working voltage to the DC motor fan when a temperature represented by a temperature signal reaches a preset temperature threshold or a heat dissipation temperature range above the temperature threshold, and then adjusting the working voltage proportionally and linearly according to the temperature signal within the heat dissipation temperature range; an upper limit of the working voltage is a rated voltage of the DC motor fan; and
turning back to the low-load period and providing the second voltage to the DC motor fan when the temperature represented by the temperature signal is dropped from the heat dissipation temperature range to be lower than the temperature threshold.

2. The method as claimed in claim 1, wherein the start period ranges from 3 to 10 seconds.

3. The method as claimed in claim 1, wherein the rated voltage of the DC motor fan is DC 12.0V while the first voltage is DC 5.0V and the second voltage is DC 3.0V.

4. A speed control method of direct current (DC) motor fans for starting and speed adjustment of the DC motor fan according to a temperature signal comprising the steps of:
using a first voltage to start the DC motor fan during a start period and providing the first voltage to the DC motor fan during the start period;
providing a working voltage to the DC motor fan during a working period which is after the end of the start period while an initial voltage of the working voltage is a second voltage which is the lowest voltage required for keeping the DC motor fan rotating; and
adjusting the working voltage proportionally and linearly according to the temperature signal during the working period and an upper limit of the working voltage is a rate voltage of the DC motor fan.

5. The method as claimed in claim 4, wherein the start period ranges from 3 to 10 seconds.

6. The method as claimed in claim 4, wherein the rated voltage of the DC motor fan is DC 12.0V while the first voltage is DC 5.0V and the second voltage is DC 3.0V.
